(19) United States
(12) Patent Application Publication
(10) Pub. No.: US 2025/0279307 A1
(43) Pub. Date: Sep. 4, 2025

(54) SUBSTRATE PROCESSING APPARATUS, METHOD OF TEACHING TRANSFER MACHINE, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventors: Takayuki OTA, Toyama-shi (JP); Yukinori ABURATANI, Toyama-shi (JP); Seiya KITO, Toyama-shi (JP); Yunosuke SAKAI, Toyama-shi (JP); Tomoki MATSUNAGA, Toyama-shi (JP)

(73) Assignee: KOKUSAI ELECTRIC CORPORATION, Tokyo (JP)

(21) Appl. No.: 18/972,651

(22) Filed: Dec. 6, 2024

(30) Foreign Application Priority Data
Mar. 1, 2024 (JP) 2024-031052

(51) Int. Cl. H01L 21/68; H01L 21/324

(52) U.S. Cl. CPC H01L 21/681; H01L 21/324

(57) ABSTRACT

There is provided a technique that includes: a controller configured to be capable of acquiring a detection result of a photoelectric sensor with an optical path set within a rotation radius of a substrate holder while rotating the substrate holder, and calculating a deviation of a center of the substrate holder based on an angle or a timing at which the optical path is blocked by the substrate holder.

### CROSS-REFERENCE TO RELATED APPLICATION

This application is based upon and claims the benefit of priority from Japanese Patent Application No. 2024-031052, filed on Mar. 1, 2024, the entire contents of which are incorporated herein by reference.

### TECHNICAL FIELD

The present disclosure relates to a substrate processing apparatus, a method of teaching a transfer machine, a method of manufacturing a semiconductor device, and a recording medium.

### BACKGROUND OF THE INVENTION

In a substrate processing in a process of manufacturing a semiconductor device, for example, a batch-type vertical substrate processing apparatus configured to process a plurality of substrates (semiconductor silicon wafers) at once may be used. In the vertical substrate processing apparatus, a substrate holder (boat) configured to hold the plurality of substrates in such a state that the wafers are arranged in a horizontal posture and in multiple stages with centers of the substrates aligned with one another is used. Further, the boat is equipped with a plurality of holders (posts) configured to hold the substrates.

Periodic maintenance is demanded for the vertical substrate processing apparatus. During maintenance work, the boat may be removed from the vertical substrate processing apparatus, and there is a risk of a positional deviation when the boat is reinstalled.

### SUMMARY OF THE INVENTION

Some embodiments of the present disclosure provide a technique capable of calculating a positional deviation of a center of a substrate holder with respect to a reference position of the substrate holder.

According to some embodiments of the present disclosure, there is provided a technique that includes: a controller configured to be capable of acquiring a detection result of a photoelectric sensor with an optical path set within a rotation radius of a substrate holder while rotating the substrate holder, and calculating a deviation of a center of the substrate holder based on an angle or a timing at which the optical path is blocked by the substrate holder.

### BRIEF DESCRIPTION OF DRAWINGS

The accompanying drawings, which are incorporated in and constitute a part of the specification, illustrate embodiments of the present disclosure.

FIG. 1 is a perspective view of a substrate processing apparatus according to some embodiments of the present disclosure.

FIG. 2 is a perspective view of a transfer machine according to some embodiments of the present disclosure.

FIG. 3 is a schematic configuration diagram of a controller of a substrate processing apparatus according to some embodiments of the present disclosure.

FIG. 4 is a flowchart for explaining a teaching process according to some embodiments of the present disclosure.

FIG. 5 is a plane view for explaining a teaching process according to some embodiments of the present disclosure.

FIGS. 6A and 6C are explanatory views showing a state where a support starts to cross a laser beam in a teaching process according to some embodiments of the present disclosure, and

FIGS. 6B and 6D are explanatory views showing a state where the support finishes crossing the laser beam.

FIG. 7 is a graph for explaining scan results of a Z-axis scan in a teaching process according to some embodiments of the present disclosure.

### DETAILED DESCRIPTION

Reference will now be made in detail to various embodiments, examples of which are illustrated in the accompanying drawings. In the following detailed description, numerous specific details are set forth to provide a thorough understanding of the present disclosure. However, it will be apparent to one of ordinary skill in the art that the present disclosure may be practiced without these specific details. In other instances, well-known methods, procedures, systems, and components are not described above in detail so as not to obscure aspects of the various embodiments.

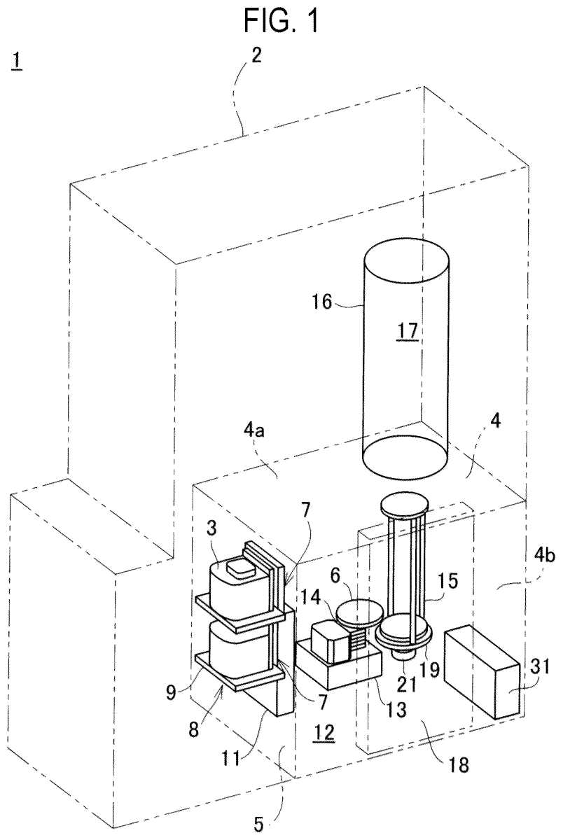

Some embodiments of the present disclosure will now be described with reference to FIGS. 1 to 3. The drawings used in the following description are schematic, and dimensional relationships, ratios, and the like of various components shown in the drawings may not match actual ones. Further, dimensional relationships, ratios, and the like of various components among plural drawings may not match one another. Further, unless specifically stated in the present disclosure, each component is not limited to one, and may be present in plural.

### (Overview of Substrate Processing Apparatus)

A substrate processing apparatus described in the embodiments of the present disclosure is used in a process of manufacturing a semiconductor device and is configured to perform a process (heat treatment) by heating a substrate, which is a processing target, with a heater in a state where the substrate is accommodated in a process chamber. More specifically, the substrate processing apparatus of the embodiments is a vertical substrate processing apparatus configured to process a plurality of substrates simultaneously in a state where the substrates are stacked vertically at a predetermined interval.

The substrate to be processed by the substrate processing apparatus may include, for example, a semiconductor wafer substrate (a wafer cassette, simply referred to as a wafer) in which a semiconductor device is fabricated. The heat treatment performed by the substrate processing apparatus may include, for example, oxidation, diffusion, annealing, reflow, baking, film formation by thermal chemical vapor deposition (CVD) reaction, film quality improvement (treatment), and the like.

### (1) Configuration of Substrate Processing Apparatus

The entire apparatus will be described with reference to FIG. 1. FIG. 1 shows main parts of a substrate processing apparatus.

The substrate processing apparatus 1 includes a housing 2. A pod 3, which is a sealed substrate container, is loaded into the substrate processing apparatus 1 by an in-process transfer apparatus (not shown) and is unloaded from the substrate processing apparatus 1.

A sub-housing 4 is installed at a rear lower side within the housing 2 in a front-rear direction such that the sub-housing 4 extends to a rear end. A pair of wafer loading/unloading ports 7 configured to load or unload a wafer 6 into or from the sub-housing 4 are arranged vertically in two stages at a front wall 5 of the sub-housing 4. Pod openers 8 are installed for upper and lower wafer loading/unloading ports 7, respectively.

Each pod opener 8 includes a mounting stand 9 on which the pod 3 is mounted, and an opening/closing mechanism 11 configured to open or close a lid of the pod 3. Each pod opener 8 is configured to open or close a wafer entrance of the pod 3 by opening or closing the lid of the pod 3 mounted on the mounting stand 9 by using the opening/closing mechanism 11.

The sub-housing 4 constitutes a transfer chamber (loading chamber or loading area) 12 that is airtight from a space in which the pod openers 8 are disposed. A transfer machine 13 is installed in a front region of the transfer chamber 12. The transfer machine 13 includes the desired number of wafer mounting plates (substrate grippers) 14 (five wafer mounting plates 14 in the drawing) configured to hold the wafers 6. Each wafer mounting plate 14 may move linearly in a horizontal direction, rotate in the horizontal direction, and move up or down in a vertical direction. The transfer machine 13 is configured to load or unload the wafers 6 into or from a boat 15 serving as a substrate holder in the transfer chamber 12. The wafer mounting plate 14 is also called a hand, an end effector, a chuck, a fork, or a tweezer, and may be constituted, for example, by five mounting plates.

A vertical process furnace 16 is installed above the transfer chamber 12. The process furnace 16 forms a process chamber 17 therein, and a lower end of a furnace opening at a lower side of the process chamber 17 is open and is opened or closed by a furnace opening shutter (not shown). The process chamber 17 heat-treats the wafers 6 held in the boat 15.

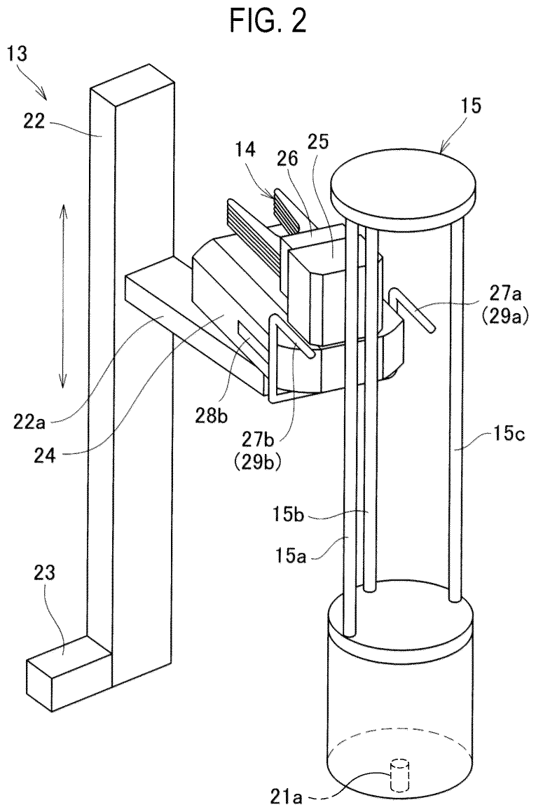

A boat elevator 18 configured to raise or lower the boat 15 is installed at a side surface of the sub-housing 4. A seal cap 19 as a lid is installed horizontally at an arm (not shown) connected to an elevating stand of the boat elevator 18. The seal cap 19 is configured to be capable of supporting the boat 15 vertically and air-tightly closing the furnace opening in a state where the boat 15 is loaded into the process furnace 16. The transfer chamber 12 is adjacent to the process chamber 17, holds the boat 15 between the process chamber 17 and the transfer chamber 12, and loads or unloads the wafers 6 with the boat 15 into or from the process chamber 17. The boat 15 is configured to hold a plurality of wafers 6 (for example, 50 to 175 wafers 6) in such a state that the wafers are arranged in a horizontal posture and in multiple stages with centers of the wafers 6 aligned with one another. As shown in FIG. 2, the boat 15 includes posts 15a to 15c as columns configured to hold the wafers 6. The posts 15a to 15c include grooves (slots) configured to hold the wafers 6. At least outer peripheral surfaces of the posts 15a to 15c are cylindrical.

A rotator 21 configured to rotate the boat 15 around a central axis corresponding to the centers of the wafers 6 is installed at an opposite side of the seal cap 19 from the process chamber 17. A rotary shaft 21a of the rotator 21 is connected to the boat 15 through the seal cap 19. The rotator 21 is a rotation driver configured to rotate the boat 15, and is configured to rotate the wafers 6 by rotating the boat 15 in the process chamber 17.

A cleaner (not shown) is disposed at a position (a first side surface 4a of the sub-housing 4) facing the boat elevator 18 (a second side surface 4b of the sub-housing 4). The cleaner includes a supply fan and a dustproof filter to supply clean air which is purified air or inert gas. The first side surface 4a of the sub-housing 4 (i.e., a first side surface of the transfer chamber 12) includes a clean air outlet. A notch aligner (not shown) as a substrate matcher configured to match a circumferential position of the wafer 6 may be installed between the transfer machine 13 and the cleaner.

After the clean air blown out from the cleaner is circulated via the notch aligner, the transfer machine 13, and the boat 15, a portion of the clean air is sucked in by a local exhaust duct (or a common exhaust duct) and the like installed at the second side surface of the transfer chamber 12 and is exhausted to an outside of the housing 2 via the exhaust duct. The second side surface 4b of the sub-housing 4 (i.e., a second side surface of the transfer chamber 12) is provided with an exhaust port. Another portion of the clean gas is blown out again into the transfer chamber 12 by the cleaner.

An example of a configuration of the transfer machine 13 will be described with reference to FIG. 2. FIG. 2 shows a state when the transfer machine 13 transfers the wafer 6 to the boat 15. That is, the wafer mounting plate (end effector) 14 of the transfer machine 13 faces the posts 15a and 15c of the boat 15.

The transfer machine 13 includes a guide 22 installed along an up-and-down direction (Z-axis direction), a Z-axis direction driver 23, a Y-axis rotation driver 24, an X-axis direction driver 25, and a V-axis direction driver 26. Each of the drivers 23 to 26 may be referred to as a drive system.

The Z-axis direction driver 23 is installed at a lower or an upper end of the guide 22 to move a mount 22a in the up-and-down direction (the Z-axis direction or the vertical direction) along the guide 22.

The Y-axis rotation driver 24 is installed at an upper surface of the mount 22a so as to be rotatable in the Y-axis direction such that the Y-axis rotation driver 24 is rotated horizontally clockwise or counterclockwise (around the Y-axis), while supporting the X-axis direction driver 25 so that the X-axis of the X-axis direction driver 25 and the Y-axis of the Y-axis rotation driver 24 are perpendicular to each other. A range of rotation is sufficient to be about 180 degrees since the pod 3 is usually positioned between a direction of the boat 15 and an opposite direction thereof as viewed from the Y-axis.

The X-axis direction driver 25 is installed integrally with or inside the Y-axis rotation driver 24 to move the V-axis direction driver 26 forward and backward in the horizontal direction (X-axis direction) while supporting the V-axis direction driver 26. The X-axis defines a direction in which the wafer mounting plate 14 moves to protrude from the Y-axis rotation driver 24 so as to enter the boat 15 or the pod 3, as “forward.”

The V-axis direction driver 26 is installed at the X-axis direction driver 25 and is configured to be capable of supporting the five wafer mounting plates 14 horizontally while adjusting a spacing between the wafer mounting plates 14 in the Z-axis direction.

This allows the transfer machine 13 to take out the wafer 6 from the pod 3 and load (charge) the same into the boat 15 by using the wafer mounting plate 14. Then, after any process is performed on the wafer 6 in the process furnace 16, the transfer machine 13 may take out (discharge) the wafer 6 from the boat 15 by the wafer mounting plate 14 and load the same into the pod 3. Further, an outer shape of the Y-axis rotation driver 24 is formed so as to be a rotation radius equal to or slightly larger than a minimum rotation radius around the Y-axis of the wafer mounting plate 14 and the V-axis direction driver 26. For example, a length of the Y-axis rotation driver 24 in the X-axis direction is equal to or slightly larger than a combined length of the wafer mounting plate 14 and the V-axis direction driver 26, and the Y-axis rotation driver 24 includes a side surface parallel to the X-axis.

The transfer machine 13 further includes sensor rods 27a and 27b as arms installed at both side surfaces of the Y-axis rotation driver 24, and advance/retreat drivers 28a and 28b configured to move the sensor rods 27a and 27b in the X-axis direction. The advance/retreat driver 28b is shown in FIG. 2.

The sensor rods 27a and 27b extend upward along both side surfaces of the Y-axis rotation driver 24 to approximately the same height as any one of the wafer mounting plates 14 and are configured to be bent at approximately a right angle in an opposite direction to a mounting direction of the wafer mounting plate 14 with respect to the X-axis direction driver 25, that is, backward in the X-axis direction. The sensor rods 27a and 27b hold fiber sensors 29a and 29b as photoelectric sensors.

Tips of the sensor rods 27a and 27b are provided with light transmitting/receiving parts of the fiber sensors 29a and 29b, respectively. The fiber sensors 29a and 29b are a pair of transmission type sensors, one of which transmits a laser beam and the other of which receives the same, and may be arranged such that an optical path (optical axis) formed between the light transmitting/receiving parts is parallel to a tangent line of the wafer 6. The fiber sensors 29a and 29b are mapping sensors configured to perform a mapping to count the number of wafers 6 loaded in the pod 3 or the boat 15 or detect normality or abnormality such as protrusion of the wafer 6 or positional deviation of the boat 15 by detecting blocking of the light path. When the sensor rods 27a and 27b advance, the optical axes are matched and horizontal. The sensor rods 27a and 27b may be interconnected via the Y-axis rotation driver 24 such that the sensor rods 27a and 27b operate in conjunction with each other, and in such a case one of the advance/retreat drivers 28a and 28b may be provided. Further, the optical path (optical axis of the laser beam) of the fiber sensors 29a and 29b is perpendicular or approximately perpendicular to the rotation axis of the rotator 21, i.e., the rotation axis of the boat 15, and is also perpendicular or approximately perpendicular to an extension direction of each of the posts 15a to 15c.

The advance/retreat drivers 28a and 28b are arranged at both side surfaces of the Y-axis rotation driver 24 to support the sensor rods 27a and 27b such that the sensor rods 27a and 27b may move in the X-axis direction between a protruding position and a storage position. That is, the wafer mounting plate 14 and the sensor rods 27a and 27b are arranged back-to-back in opposing directions with respect to the Y-axis rotation driver 24 and may move independently from each other on the X-axis. The sensor rods 27a and 27b may be moved by the Z-axis direction driver 23 along the longitudinal direction (the up-and-down direction or the Z direction) of the posts 15a to 15c of the boat 15.

This allows the transfer machine 13 to map the wafers 6 in the pod 3 by using the fiber sensors 29a and 29b. The transfer machine 13 may also use the fiber sensors 29a and 29b to map the wafers 6 in the boat 15 and detect a positional deviation in the XY-axis direction between a reference position and a current position of the boat 15. Herein, the reference position of the boat 15 is a position where the boat 15 is vertically installed in a state where a center of the boat 15 is matched with a rotational center of the boat 15 (the rotator 21), and the rotational center of the boat 15 may be considered as the reference position. A height (height position information) of each wafer slot (not shown) configured to hold the wafers 6 in this case may be included in the reference position. Further, a positive X-axis direction of a coordinate system with the reference position as an origin, for example, a direction parallel to the optical path of the fiber sensors 29a and 29b, is set as the reference angle (0 degrees).

As shown in FIG. 2, the sensor rods 27a and 27b of the transfer machine 13 are moved by the Y-axis rotation driver 24 in a direction approaching the boat 15, that is, in a direction in which the X-axis faces the center of the boat 15. Further, when the boat 15 is rotated by the rotator 21, one of the posts 15a to 15c of the boat 15 is positioned so as to block a laser beam emitted from one of the fiber sensors 29a and 29b. In FIG. 2, the post 15b is positioned to be closest to the Y-axis of the transfer machine 13, that is, on the X-axis.

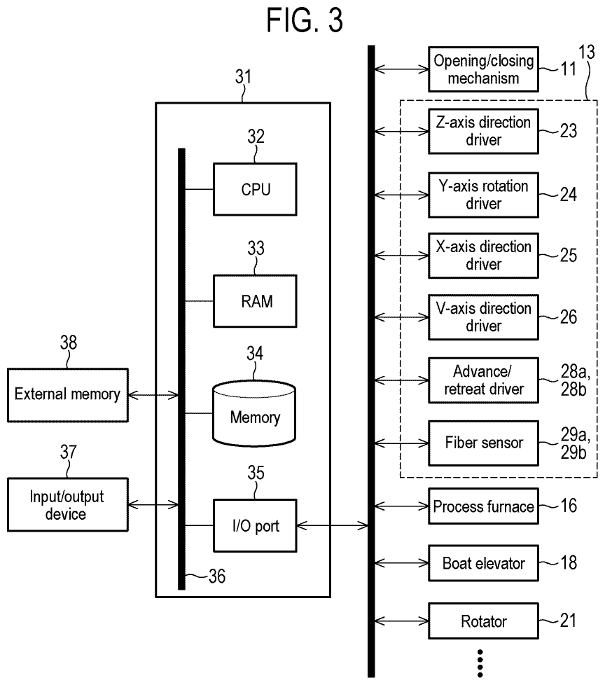

Further, a controller 31, which is a control part (a control equipment or a control means or unit), is installed at a desired position in the housing 2, for example, at a corner of the sub-housing 4 in FIG. 1. As shown in FIG. 3, the controller 31 is constituted as a computer including a CPU (Central Processing Unit) 32, a RAM (Random Access Memory) 33, a memory 34, and an I/O port 35. The RAM 33, the memory 34, and the I/O port 35 are configured to be capable of exchanging data with the CPU 32 via an internal bus 36. An input/output device 37 constituted as, for example, a touch panel is connected to the controller 31. An external memory 38 may also be connected to the controller 31.

The memory 34 includes, for example, a flash memory, a hard disk drive (HDD), a solid state drive (SSD), and the like. A control program that controls an operation of the substrate processing apparatus, a process recipe in which procedures and conditions of substrate processing, which will be described later, are written, and the like are readably stored in the memory 34. The process recipe functions as a program that causes, by the controller 31, the substrate processing apparatus to perform each sequence in a substrate processing process, which will be described later, to obtain an expected result. Hereinafter, the process recipe and the control program may be generally and simply referred to as a “program.” Further, the process recipe may be simply referred to as a “recipe.” When the term “program” is used herein, it may indicate a case of including a recipe, a case of including a control program, or a case of including both the recipe and the control program. The RAM 33 is constituted as a memory area (work area) in which programs or data read by the CPU 32 are temporarily stored.

The I/O port 35 is connected to the above-described opening/closing mechanism 11, transfer machine 13, process furnace 16, boat elevator 18, rotator 21, and the like.

The CPU 32 is configured to be capable of reading and executing the control program from the memory 34 and also reading the recipe from the memory 34 in response to an input of an operation command from the input/output device 37. The CPU 32 is configured to be capable of controlling the lid opening/closing operation of the pod 3, the transferring operation of the wafer 6 by the transfer machine 13, the supplying/exhausting operation of the process gas into the process furnace 16, the flow rate regulating operation of the process gas, the pressure controlling/temperature regulating operation of the process chamber 17, the operation of moving the boat 15 up or down by the boat elevator 18, the operation of rotating the boat 15 and adjusting the rotation speed of the boat 217 with the rotator 21, and the like, in accordance with the contents of the read recipe.

The controller 31 may be constituted by installing, on the computer, the above-described program stored in the external memory 38. The external memory 38 is, for example, a magnetic disk such as a HDD, an optical disc such as a CD, a magneto-optical disc such as a MO, a semiconductor memory such as a USB memory or a SSD, and the like. The memory 34 and the external memory 38 are configured as a computer-readable recording medium. Hereinafter, the memory 34 and the external memory 38 may be generally referred to simply as a “recording medium.” When the term “recording medium” is used herein, it may indicate a case of including the memory 34, a case of including the external memory 38, or a case of including both the memory 34 and the external memory 38. Further, the program may be provided to the computer by using communication means or unit such as the Internet or a dedicated line, instead of using the external memory 38.

### (2) Teaching Process

Herein, when performing a maintenance on the substrate processing apparatus 1, various components are removed from the housing 2 and the sub-housing 4, and various processes such as cleaning and replacement are performed. In particular, when the boat 15 is reinstalled, the transfer machine 13 charges or discharges the wafer 6 into or from the boat 15 based on information of the reference position. That is, the reference position of the boat 15 is set in advance in a program to perform a transfer process on the wafer 6, wafer transfer position information indicating a center position of the wafer 6 when the wafer 6 is transferred to the boat 15 based on the reference position is set, and the wafer 6 is transferred based on the wafer transfer position information. Therefore, in a case where there is a deviation between an installation position of the boat 15 and the reference position, the wafer 6 or the wafer mounting plate 14 may come into contact with the posts 15a to 15c of the boat 15.

In the embodiments of the present disclosure, as a pre-process of a substrate processing process, a teaching process is performed in which the center position of the reinstalled boat 15 is automatically detected, a difference between the reference position and the detected position is acquired, and the wafer transfer position information is corrected based on the difference to acquire new wafer transfer position information.

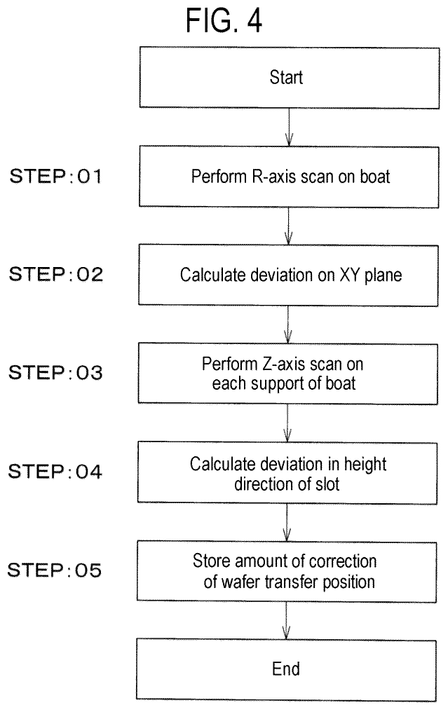

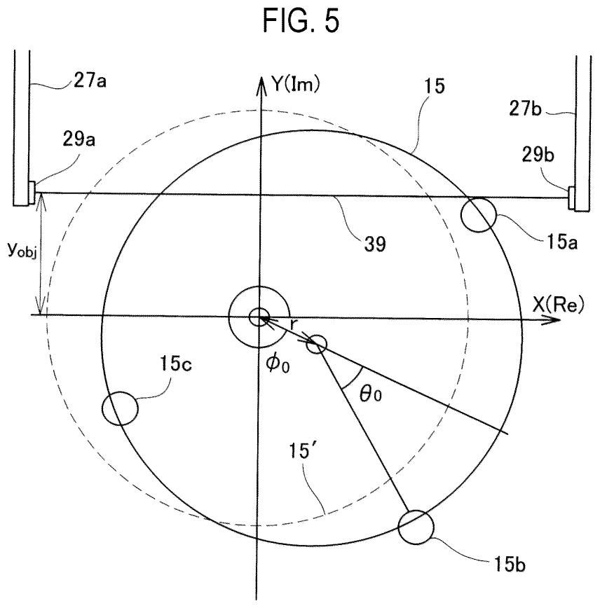

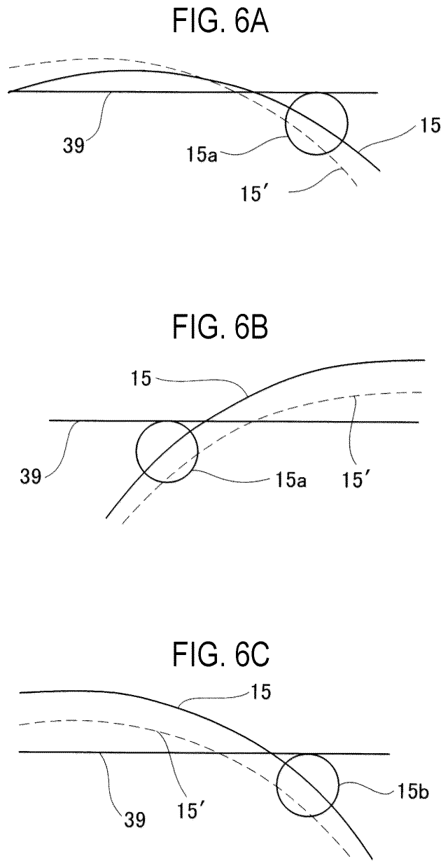

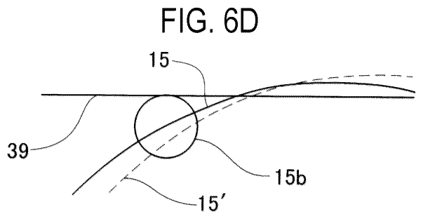

Below, the teaching process in the embodiments of the present disclosure will be described with reference to a flowchart in FIG. 4, and FIGS. 5 to 7. In the following description, an operation or a processing of each component constituting the substrate processing apparatus 1 are controlled by the controller 31 according to a teaching program. In FIGS. 5 and 6A to 6D, a boat 15′ at the reference position is indicated by a broken line, and an actual boat 15 is indicated by a solid line.

STEP: 01 As a pre-step of an automatic teaching process, the center position of the boat 15 before removal is acquired as the reference position.

The reference position may be acquired by manually aligning a position of the boat 15 by using a jig to match the center of the boat 15 with the reference position, or by performing a teaching process, which will be described below, on the boat 15 before removal and registering (storing) the center of the boat 15 acquired by the teaching process as a new reference position.

As shown in FIG. 5, the controller 31 drives the Z-axis direction driver 23, the Y-axis rotation driver 24, the X-axis direction driver 25, the V-axis direction driver 26, and the advance/retreat drivers 28a and 28b such that a portion of the boat 15 is positioned between the sensor rods 27a and 27b. That is, the transfer machine 13 is moved such that an optical path of a laser beam 39 emitted from the fiber sensors 29a and 29b is located within the rotation radius of the boat 15 at the reference position or such that the posts 15a to 15c cross the optical axis of the laser beam 39.

The controller 31 moves the transfer machine 13 to a first height (Z1), and while activating the fiber sensors 29a and 29b, rotates the boat 15 around the rotation axis of the boat 15 (R-axis direction) at a constant speed by using the rotator 21 to perform an R-axis scan.

When any one of the posts 15a to 15c crosses between the fiber sensors 29a and 29b, the laser beam 39 is blocked by the post 15a, for example, from the time when the post 15a starts to cross the laser beam 39 (see FIG. 6A) until the post 15a completely crosses the laser beam 39 (see FIG. 6B), such that reception of the laser beam 39 by the light receiving parts of the fiber sensors 29a and 29b is stopped. Further, the laser beam 39 is blocked by the cylindrical outer periphery of each of the posts 15a to 15c. That is, the side surface of each of the posts 15a to 15c enters the optical path of the laser beam 39 from a tangential direction and blocks the laser beam 39, such that a blocking timing may be detected with high accuracy.

The controller 31 detects a rotation speed of the boat 15 at this time, a time from when each of the posts 15a to 15c starts to cross the laser beam 39 to when the crossing is finished, and a time (timing) from when the crossing is finished to when the next post starts to cross the laser beam 39, and stores the same in the memory 34. The controller 31 also executes R-axis scans at a second height (Z2) different from the first height and at a third height (Z3) different from the first height and the second height, and stores scan results in the memory 34. Further, in STEP: 01, the R-axis scans are performed at three different heights, but the R-axis scans may be performed at two different heights or at four or more different heights. Further, since the optical path of the laser beam 39 emitted from the fiber sensors 29a and 29b is perpendicular or approximately perpendicular to the rotation axis of the boat 15, timings of starting and finishing the crossing may be detected with high accuracy.

STEP: 02 Based on the scan results of the R-axis scans at three different heights (Z1 to Z3) performed in STEP: 01, a deviation amount r on the XY-axis plane between the center of the boat 15 at the first height and the reference position is calculated. A deviation angle (deviation rotation angle) φ₀ of the center of the boat 15 with respect to the reference angle is calculated. Further, an angle (direction angle) θ₀ indicating a relationship between the deviation direction of the center of the boat 15 and the orientation of the boat 15 (for example, the direction of the post 15b), that is, a direction angle θ₀ which is a second predetermined rotation angle with respect to the reference angle which is a first predetermined rotation angle, is calculated. These deviation amount r, deviation angle φ₀, and direction angle θ₀ are calculated for the second height and the third height in the same manner. A method of calculating the deviation amount r, the deviation angle φ₀, and the direction angle θ₀ at the first height will be described below.

A point Z(tₙ) on a circumference of the boat 15 at time tₙ may be expressed by the following equation.

$$Z ( {t}_{n} ) = {Z}_{0} + {re}^{j ( ω t + φ0 )} + {Re}^{j ( ω t + φ0 + θ x + θ0 )} + ja \qquad ( Eq . 1 )$$

In Eq. 1, Z₀ indicates, for example, an origin of a coordinate system with the reference position as the origin, and may be expressed as X₀+jY₀. Further, ω indicates a rotation frequency of the boat 15, R indicates a radius of the boat, and a indicates a radius of the post, which are known values. Further, θₓ indicates positions of the posts 15a to 15c. For example, in a case where the post 15b is used as a reference, then θ_{B}=0, and the position of the post 15a at this time may be expressed as θ_{B}−θ_{A}=94.7±0.37/2 (deg), and the position of the post 15c may be expressed as θ_{C}−θ_{B}=94.7±0.37/2 (deg). Further, in FIG. 5, Y_{obj} indicates a distance in the Y-axis direction from the reference position to the optical path of the laser beam 39.

In the embodiments, as shown in FIGS. 6A to 6D, the deviation amount r, the deviation angle φ₀, and the direction angle θ₀ are calculated by using four times: time t₁ when the post 15a starts crossing the laser beam 39, time t₂ when the post 15a finishes crossing the laser beam 39, time t₃ when the post 15b starts crossing the laser beam 39, and time t₄ when the post 15b finishes crossing the laser beam 39. The followings show equations for calculating the distances (Y_{obj}) in the Y-axis direction from the reference position to the optical path of the laser beam 39 at times t₁ to t₄.

$${Y}_{obj} = Im [ Z ( {t}_{1} ) ] = Im [ {Z}_{0} + ( r + {Re}^{j ( θ A + θ0 )} ) {e}^{j ( ω t 1 + φ0 )} + ja ] = {Y}_{0} + r sin ( ω {t}_{1} + {φ}_{0} ) + R sin ( ω {t}_{1} + {φ}_{0} + {θ}_{A} + {θ}_{0} ) + a \qquad ( Eq . 2 )$$

$${Y}_{obj} = Im [ Z ( {t}_{2} ) ] = Im [ {Z}_{0} + ( r + {Re}^{j ( θ A + θ0 )} ) {e}^{j ( ω t 2 + φ0 )} + ja ] = {Y}_{0} + r sin ( ω {t}_{2} + {φ}_{0} ) + R sin ( ω {t}_{2} + {φ}_{0} + {θ}_{A} + {θ}_{0} ) + a \qquad ( Eq . 3 )$$

$${Y}_{obj} = Im [ Z ( {t}_{3} ) ] = Im [ {Z}_{0} + ( r + {Re}^{j ( θ B + θ0 )} ) {e}^{j ( ω t 3 + φ0 )} + ja ] = {Y}_{0} + r sin ( ω {t}_{3} + {φ}_{0} ) + R sin ( ω {t}_{3} + {φ}_{0} + {θ}_{B} + {θ}_{0} ) + a \qquad ( Eq . 4 )$$

$${Y}_{obj} = Im [ Z ( {t}_{4} ) ] = Im [ {Z}_{0} + ( r + {Re}^{j ( θ B + θ0 )} ) {e}^{j ( ω t 4 + φ0 )} + ja ] = {Y}_{0} + r sin ( ω {t}_{4} + {φ}_{0} ) + R sin ( ω {t}_{4} + {φ}_{0} + {θ}_{B} + {θ}_{0} ) + a \qquad ( Eq . 5 )$$

Here, regardless of time tₙ, since the distance (Y_{obj}) in the Y-axis direction from the reference position to the optical path of the laser beam 39 does not change, (Eq. 2)=(Eq. 3)=(Eq. 4)=(Eq. 5), and so, for example, the following three equations are established:

$$2 r cos \{ ω ( {t}_{2} + {t}_{1} ) / 2 + {φ}_{0} \} sin \{ ω ( {t}_{2} - {t}_{1} ) / 2 \} + 2 R cos \{ ω ( {t}_{2} + {t}_{1} ) / 2 + {φ}_{0} + {θ}_{A} + {θ}_{0} \} sin \{ ω ( {t}_{2} - {t}_{1} ) / 2 \} = 0 \qquad ( Eq . 6 )$$

$$2 r cos \{ ω ( {t}_{3} + {t}_{1} ) / 2 + {φ}_{0} \} sin \{ ω ( {t}_{3} - {t}_{1} ) / 2 \} + 2 R cos \{ ω ( {t}_{3} + {t}_{1} ) / 2 + {φ}_{0} + ( {θ}_{B} + {θ}_{A} ) / 2 + {θ}_{0} \} sin \{ ω ( {t}_{3} - {t}_{1} ) / 2 + ( {θ}_{B} - {θ}_{A} ) / 2 \} = 0 \qquad ( Eq . 7 )$$

$$2 r cos \{ ω ( {t}_{4} + {t}_{2} ) / 2 + {φ}_{0} \} sin \{ ω ( {t}_{4} - {t}_{2} ) / 2 \} + 2 R cos \{ ω ( {t}_{4} + {t}_{2} ) / 2 + {φ}_{0} + ( {θ}_{B} + {θ}_{A} ) / 2 + {θ}_{0} \} sin \{ ω ( {t}_{4} - {t}_{2} ) / 2 + ( {θ}_{B} - {θ}_{A} ) / 2 \} = 0 \qquad ( Eq . 8 )$$

Eq. (6) shows the calculation result of Eq. (3)−Eq. (2)=0, Eq. (7) shows the calculation result of Eq. (4)−Eq. (2)=0, and Eq. (8) shows the calculation result of Eq. (5)−Eq. (3)=0. By solving simultaneous equations by using the three equations Eq. (6) to Eq. (8), the deviation amount r, the deviation angle φ₀, and the direction angle θ₀ may be calculated, and the deviation on the horizontal plane (XY-axis direction) between the center of the boat 15 at the first height and the reference position may be calculated. Since these Eq. (6) to Eq. (8) are nonlinear simultaneous equations, the equations may be found by a numerical calculation such as Newton's method. In a case where there are four or more variables, the variables are calculated by creating nonlinear simultaneous equations whose number is equal to or more than the number of the variables.

Further, how much the center of the boat 15 is deviated from the reference position when the boat 15 is at the reference angle (first predetermined angle) may be founded by using the deviation amount r and the deviation angle φ₀, and a direction in which the center of the boat 15 is deviated from the reference position may be founded by using the direction angle θ₀ (second predetermined angle). Therefore, in a case where the deviation amount is to be founded, the direction angle θ₀ may not be calculated.

Similarly, for the second height and the third height, the deviation amount r, the deviation angle φ₀, and the direction angle θ₀ may be calculated to calculate the deviation on the horizontal plane (XY-axis direction) between the center of the boat 15 at the second height and the third height and the reference position. Further, an inclination of the boat 15 may be calculated based on the center of the boat 15 at the first height to the third height.

STEP: 03 When the deviation of the boat 15 in the XY-axis direction is calculated, the Z-axis scan for each of the posts 15a to 15c is started. The following describes a case where the Z-axis scan for the post 15a is performed.

In the Z-axis scanning step, first, the transfer machine 13 and the boat 15 are moved to a Z-axis scan start position. For example, based on the position and direction of the boat 15 detected in STEP: 02, the transfer machine 13 is moved to a lower end of the post 15a, the boat 15 is rotated such that a wafer slot (not shown) of the post 15a is positioned on the optical path of the laser beam 39, and the Z-axis scan is performed.

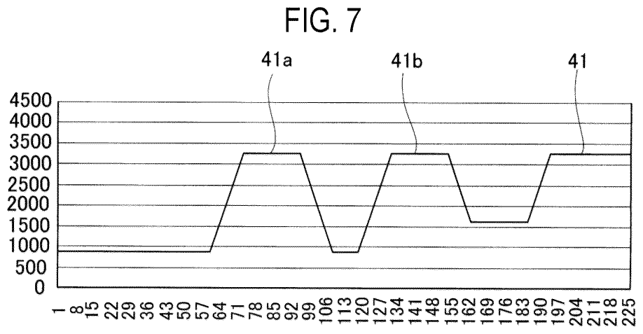

When the Z-axis scan is performed, the fiber sensors 29a and 29b are operated while the rotation of the boat 15 is stopped, and the transfer machine 13 is moved upward along the post 15a. FIG. 7 is a graph showing Z-axis scan results (detection results of the fiber sensors 29a and 29b) when a vertical axis represents a light reception amount of the laser beam 39 (arbitrary unit) detected by the fiber sensors 29a and 29b and a horizontal axis represents a height of the post 15a (arbitrary unit). The Z-axis scan may be performed by moving the transfer machine 13 downward along the post 15a from a top end of the post 15a.

When the laser beam 39 is blocked by the post 15a, that is, when there is no wafer slot on the optical path of the laser beam 39, the light reception amount of laser beam 39 received by the fiber sensors 29a and 29b is minimized. When a wafer slot is present on the optical path of the laser beam 39, the light reception amount of laser beam 39 emitted from one of the fiber sensors 29a and 29b becomes maximum, and the maximum light reception amount is continued until the wafer slot is interrupted. Therefore, a position (height) of the wafer slot may be detected based on a reception state of the laser beam 39 and a height of the laser beam 39 at that time.

Further, in a graph 41 of FIG. 7, due to a predetermined diameter of the laser beam 39, the light reception amount of 1 received laser beam 39 gradually increases from a minimum to a maximum. To estimate a shape of an actual wafer slot, for example, the light reception amount of laser beam 39 is subject to a threshold processing with an intermediate value between the maximum light reception amount and the minimum light reception amount.

When the boat 15 is upright, that is, when the rotation axis of the boat 15 is vertical, by the Z-axis scan, a scan result is obtained in which a trapezoidal waveform 41a with a height corresponding to a difference in a light amount between the minimum light reception amount and the maximum light reception amount, is repeated at an equal interval. On the other hand, when the boat 15 is tilted, since a portion of the laser beam 39 is received and the remaining portion of the laser beam 39 is blocked by the wafer slot, a trapezoidal waveform 41b with a reduced difference (height) in the light amount of the light reception amount is obtained. The light reception amount obtained by the Z-axis scan is stored in the memory 34 in association with the height of the transfer machine 13, that is, the height of the optical path of the laser beam 39. Information on the position (height) of the wafer slot acquired based on the light reception amount of laser beam 39 and the height of the optical path of the laser beam 39 may be stored in the memory 34.

The Z-axis scan is also performed on each of the posts 15b and 15c, and the light reception amount of the laser beam 39 is stored in the memory 34 in association with the height of the optical path of the laser beam 39.

STEP: 04 The controller 31 compares the scan results of the Z-axis scan for each of the posts 15a to 15c with slot position information for each of the posts 15a to 15c at the reference position and calculates a deviation amount in the Z-axis direction (rotation axis direction) of each slot, that is, a deviation amount in the Z-axis direction of the boat 15 with respect to the reference position. Further, based on the height of the trapezoidal waveform obtained by the Z-axis scan, the inclination and shape of the wafer slot, that is, the inclination and deformation of the boat 15, may also be calculated.

STEP: 05 Based on the deviation amount in the XY-axis direction calculated in STEP: 02 and the deviation amount in the Z-axis direction calculated in STEP: 04, the controller 31 calculates the position information (height information) of the boat 15 (the wafer slot). Further, based on the calculated positional deviation and height deviation of the center of the boat 15 and the direction angle θ₀ of the boat 15, new wafer transfer position information for transferring the wafer 6 to each wafer slot of the boat 15 is calculated.

That is, an amount of correction of the center position of the wafer 6 at the calculated position with respect to the center position of the wafer 6 at the reference position is calculated. The calculated amount of correction is stored in the memory 34, or alternatively, the wafer transfer position information updated based on the amount of correction is stored in the memory 34, and the teaching process is terminated.

### (3) Substrate Processing Process

A substrate processing process of processing a substrate by using the substrate processing apparatus 1 as a semiconductor manufacturing apparatus will be described schematically. This substrate processing process is, for example, a process to manufacture a semiconductor device. In the following description, the operation and processing of each component constituting the substrate processing apparatus 1 are controlled by the controller 31.

### (Substrate-Loading Step)

When the pod 3 is supplied to the substrate processing apparatus 1, the pod 3 is transferred to the mounting stand 9. An opening side end surface of the pod 3 mounted on the mounting stand 9 is pressed against an opening edge of the wafer loading/unloading port 7 at the front wall 5 of the sub-housing 4, and the lid of the pod 3 is removed by the opening/closing mechanism 11 to open the wafer entrance.

When the pod 3 is opened by the pod opener 8, the sensor rods 27a and 27b of the transfer machine 13 are moved to a protruding position (a direction approaching the pod 3) by the advance/retreat drivers 28a and 28b. Then, the sensor rods 27a and 27b are moved vertically at a constant speed by the Z-axis direction driver 23, and the wafers 6 are mapped by the fiber sensors 29a and 29b, thereby detecting the wafers 6 in the pod 3 sequentially.

After the mapping operation is completed, the sensor rods 27a and 27b return to their retracted positions. Then, in accordance with the wafer transfer position information corrected based on the amount of correction obtained in the teaching step, by sequentially repeating the advance, rise, and retreat of the wafer mounting plate 14, the rotation of the Y-axis rotation driver 24, and the advance, fall, and retreat of the wafer mounting plate 14, the wafers 6 are picked up from the pod 3 via the wafer loading/unloading port 7 and are loaded (charged) into the boat 15.

After the loading is completed, the lower end of the process furnace 16 closed by the furnace opening shutter, is opened by the furnace opening shutter. Subsequently, the boat 15 holding the wafers 6 is loaded from the transfer chamber 12 into the process furnace 16 as the seal cap 19 is raised (boat-up) by the boat elevator 18.

### (Film-Forming Step)

After the loading, the wafers 6 are heat-treated in the process chamber 17 in the process furnace 16.

### (Substrate-Unloading Step)

Next, the boat 15 on which the heat-treated wafers 6 are placed is unloaded (boat-unloading) from the process chamber 17 to the transfer chamber 12. Then, the boat 15 cools the heat-treated wafers 6.

After the cooling, the sensor rods 27a and 27b of the transfer machine 13 move to the protruding position by the advance/retreat drivers 28a and 28b. Then, the sensor rods 27a and 27b are moved vertically by the Z-axis direction driver 23, and the fiber sensors 29a and 29b perform the mapping operation of the wafers 6. When the mapping operation is finished, the sensor rods 27a and 27b return to their storage positions, and the wafers 6 are transferred by the wafer mounting plate 14 according to the wafer transfer position information and are unloaded to the pod 3. After that, the pod 3 is unloaded to an outside of the housing 2.

According to these embodiments, one or more effects set forth below are achieved.

In the embodiments of the present disclosure, when the boat 15 removed for maintenance or the like is reinstalled, the deviation amount of the reinstalled boat 15 from the reference position may be automatically detected by the fiber sensors 29a and 29b used when the mapping is performed.

Therefore, the boat 15 may not be manually installed at the reference position by an operator who uses a jig, thereby reducing a work time and a work amount. Further, no component is demanded for obtaining the deviation amount of the boat 15 from the reference position, which may reduce a manufacturing cost.

Further, since the transfer machine 13 and the rotator 21 operate automatically and the teaching process is performed based on a preset teaching program, the transfer machine 13 and the rotator 21 may not be manually operated by the operator, which may reduce an operation labor.

Since the wafer transfer position information is automatically updated by the teaching process, damage and particle generation due to contact of the wafers 6 and the wafer mounting plate 14 transferred by the transfer machine 13 with the posts 15a to 15c may be prevented.

Further, in the teaching process, since the inclination of each of the posts 15a to 15c may be obtained by performing the Z-axis scan on each of the posts 15a to 15c of the boat 15, deformation of the boat may be automatically detected.

Further, since the teaching process is performed automatically, the operator may not work inside the housing 2, such that cleanliness inside the substrate processing apparatus 1 may be maintained.

Further, in the embodiments of the present disclosure, when calculating the deviation amount of the boat 15 from the reference position, two of the posts 15a to 15c are used, but the deviation amount may be calculated by using three posts 15a to 15c. In this case, the deviation amount r, the deviation angle φ₀, and the direction angle θ₀ may be calculated by solving five simultaneous equations. Further, even in a case where a boat with four or more posts is used, the deviation amount r, the deviation angle φ₀, and the direction angle θ₀ may be calculated by solving simultaneous equations whose number is equal to or more than the number of variables.

Further, in the embodiments of the present disclosure, the deviation in the XY-axis direction is calculated at three different heights, but the deviation calculated at each height may be fitted as a function of the rotation axis direction of the boat 15, and the deviation amount r, the deviation angle φ₀, and the direction angle θ₀ may be calculated based on a result of the fitting.

Further, in the embodiments of the present disclosure, when the posts 15a to 15c cross the laser beam 39, the center deviation of the boat 15 from the reference position is calculated based on the start time and the end time of the crossing, i.e., the timings. On the other hand, the center deviation of the boat 15 from the reference position may be calculated based on an angle with respect to the reference angle when the posts 15a to 15c cross the laser beam 39.

Further, in the embodiments of the present disclosure, when performing the R-axis scan, the boat 15 is constantly rotated at a constant speed, but the boat 15 may be rotated at a constant speed while the optical path of the laser beam 39 is blocked, that is, while any one of the posts 15a to 15c is blocking the optical path of the laser beam 39. For example, the rotation of the boat 15 may be decelerated while the optical path of the laser beam 39 is blocked, or the rotation speed of the boat 15 may be variable while the optical path of the laser beam 39 is not blocked. While the optical path of the laser beam 39 is blocked, the rotation speed of the boat 15 is constant, such that the start and end times of the blocking may be accurately detected.

In addition, when the deviation amount r, the deviation angle φ₀, and the direction angle θ₀ are acquired by using the three or more posts, an optimal solution (least square solution) may be calculated by using equations whose number is equal to or larger than the number of variables. Further, AI may be used to perform the calculation based on a prediction model created by machine learning with results of manual teaching as teacher data.

Further, in the embodiments of the present disclosure, θ_{A} and θ_{C} (θ_{B}−θ_{A}, θ_{C}−θ_{B}) are known constants when calculating the deviation amount in the XY-axis direction, but θ_{A} and θ_{C} may be calculated as a difference in a rotation axis angle when the laser beam 39 is blocked by the posts 15a to 15c. Alternatively, θ_{A}, φ₀+θ, and θ_{C} may be directly obtained as an intermediate angle between the start and the end of blocking of the laser beam 39 by the posts 15a to 15c. Further, by comparing θ_{A}, φ₀+θ, and θ_{C} with design values, a tangential displacement of the post may be determined, and even in case of the displacement, a positional deviation may be calculated with high accuracy.

According to the present disclosure in some embodiments, it is possible to calculate a positional deviation of a center of a substrate holder from a reference position of the substrate holder.

While certain embodiments are described above, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a controller configured to be capable of acquiring a detection result of a photoelectric sensor with an optical path set within a rotation radius of a substrate holder while rotating the substrate holder, and calculating a deviation of a center of the substrate holder based on an angle or a timing at which the optical path is blocked by the substrate holder.

2. The substrate processing apparatus of claim 1, further comprising a process chamber in which a substrate held by a plurality of posts of the substrate holder is heat-treated, wherein the controller is configured to be capable of calculating the deviation based on an angle or a timing at which the optical path is blocked by the plurality of posts.

3. The substrate processing apparatus of claim 1, further comprising the photoelectric sensor with the optical path perpendicular or approximately perpendicular to a rotation axis of the substrate holder.

4. The substrate processing apparatus of claim 1, further comprising:
a process chamber in which a substrate held by a plurality of posts of the substrate holder is heat-treated;
a transfer chamber which is adjacent to the process chamber and in which the substrate holder is capable of being placed;
a transfer machine configured to load or unload the substrate into or from the substrate holder in the transfer chamber; and
a rotation driver configured to rotate the substrate holder within the process chamber.

5. The substrate processing apparatus of claim 4, wherein the photoelectric sensor is a mapping sensor which is mounted on the transfer machine, includes an optical axis perpendicular or approximately perpendicular to an extension direction of the plurality of posts, and is configured to detect the substrate in the substrate holder by blocking of the optical axis.

6. The substrate processing apparatus of claim 4, wherein the deviation is calculated when a rotary shaft of the rotation driver is at a first predetermined rotation angle, and the controller is configured to determine an amount of correction to correct a center position of a substrate to be transferred to the substrate holder based on the deviation when the rotary shaft is at a second predetermined rotation angle.

7. The substrate processing apparatus of claim 1, wherein the controller is configured to be capable of calculating the deviation by fitting a deviation, which is calculated at each of a plurality of different positions in a rotation axis direction of the substrate holder, as a function of the rotation axis direction.

8. The substrate processing apparatus of claim 2, wherein the controller is configured to be capable of controlling the substrate holder to rotate at a constant speed while at least one post selected from the group of the plurality of posts blocks the optical path.

9. The substrate processing apparatus of claim 1, wherein the controller is configured to be capable of acquiring the detection result of the photoelectric sensor while moving the optical path along one of a plurality of posts of the substrate holder without rotating the substrate holder, and calculating a position of a slot of the substrate holder in a rotation axis direction of the substrate holder based on blocking of the optical path corresponding to the slot.

10. The substrate processing apparatus of claim 2, wherein the controller is configured to be capable of calculating the deviation, assuming that at least outer peripheral side surfaces of the plurality of posts are cylindrical.

11. The substrate processing apparatus of claim 10, wherein the controller is configured to be capable of calculating the deviation by using a rotation angle or a timing of the substrate holder when the optical path is blocked by an outer periphery of each of the plurality of posts or when the blocking is released.

12. The substrate processing apparatus of claim 1, wherein the controller is configured to be capable of numerically calculating solutions to three or more nonlinear equations including a positional deviation of the center of the substrate holder with respect to a rotation axis of the substrate holder and an angular deviation of the substrate holder with respect to a reference angle as unknown quantities.

13. A method of teaching a transfer machine, comprising:
acquiring a detection result of a photoelectric sensor with an optical path set within a rotation radius of a substrate holder while rotating the substrate holder; and
calculating a deviation of a center of the substrate holder based on an angle or a timing at which the optical path is blocked by the substrate holder.

14. A method of manufacturing a semiconductor device, comprising:
correcting a transfer position by an amount of the deviation calculated by the method of claim 13, and transferring a substrate from a container to the substrate holder; and
loading the substrate holder into a process chamber and processing the substrate.

15. A non-transitory computer-readable recording medium storing a program that causes, by a computer, a substrate processing apparatus to perform a process comprising:
acquiring a detection result of a photoelectric sensor with an optical path set within a rotation radius of a substrate holder while rotating the substrate holder; and
calculating a deviation of a center of the substrate holder based on an angle or a timing at which the optical path is blocked by the substrate holder.
